(19) United States
(12) Patent Application Publication
(10) Pub. No.: US 2023/0172035 A1
(43) Pub. Date: Jun. 1, 2023

(54) DISPLAY DEVICE

(71) Applicant: SHARP KABUSHIKI KAISHA, Sakai City, Osaka (JP)

(72) Inventor: MASANOBU MIZUSAKI, Sakai City, Osaka (JP)

(21) Appl. No.: 17/925,326

(22) PCT Filed: May 18, 2020
(86) PCT No.: PCT/JP2020/019598

§ 371 Date: Nov. 15, 2022

(51) Int. Cl. H10K 59/80; H10K 59/35; C09K 3/10; C08F 220/12

(52) U.S. Cl. CPC H10K 59/8731; H10K 59/35; C09K 3/10; C08F 220/12; H10K 59/12

(57) ABSTRACT

A display device includes: s light-emitting element layer (11) including, on a thin film transistor layer (6), a plurality of light-emitting elements (11R, 11G, 11B) that each include a first electrode (7), a light-emitting-layer-including functional layer (9R, 9G, 9B), and a second electrode (10) and that emit light of different colors; and a sealing layer (12) disposed on the light-emitting element layer (11) so as to seal the light-emitting element layer (11), wherein the sealing layer (12) includes a first inorganic sealing film (12a) on the light-emitting element layer (11) and an organic sealing film (12b) on the first inorganic sealing film (12a), and the organic sealing film (12b) contains a polymer compound and a cyclic compound.

### TECHNICAL FIELD

The present disclosure relates to display devices.

### BACKGROUND ART

Much attention has been paid to, for example, OLED (organic light-emitting diode) display devices and QLED (quantum-dot light-emitting diode) display devices (see, e.g., Patent Literature 1 listed below).

### CITATION LIST

### Patent Literature

Patent Literature 1: PCT International Application Publication No. WO2018/179168 A1 (Publication Date: Oct. 4, 2018)

### SUMMARY OF INVENTION

### Technical Problem

Patent Literature 1 describes a display device including a sealing layer in which a first inorganic sealing film, an organic sealing film, and a second inorganic sealing film, among others, are provided in this order on a light-emitting element layer. However, this sealing layer could in some cases exhibit poor adhesion between the organic sealing film and the first inorganic sealing film and between the organic sealing film and the second inorganic sealing film, so that an undesirable gap may develop between the organic sealing film and the first inorganic sealing film and between the organic sealing film and the second inorganic sealing film. It is therefore difficult to improve barrier properties in the conventional display device, which can pose an issue.

The present disclosure, in an aspect thereof, has been made in view of this issue and has an object to provide a display device with good barrier properties.

### Solution to Problem

To address the issue, the present disclosure is directed to a display device including: a display area including a plurality of pixels; a frame area surrounding the display area; a thin film transistor layer; a light-emitting element layer on the thin film transistor layer in the display area, the light-emitting element layer including a plurality of light-emitting elements that each include a first electrode, a light-emitting layer, and a second electrode and that emit light of different colors; and a sealing layer disposed on the light-emitting element layer to seal the light-emitting element layer, wherein the sealing layer includes a first inorganic sealing film on the light-emitting element layer and an organic sealing film on the first inorganic sealing film, and the organic sealing film contains a polymer compound and a cyclic compound.

### Advantageous Effects of Invention

The present disclosure, in an aspect thereof, can provide a display device with good barrier properties.

### BRIEF DESCRIPTION OF DRAWINGS

Portion (a) of FIG. 1 is a plan view of a display device in accordance with Embodiment 1, (b) is a cross-sectional view of a structure of the display device in accordance with Embodiment 1.

FIG. 2 is a partially enlarged view of a pixel section in the display device in accordance with Embodiment 1.

FIG. 3 is a diagram listing the external quantum efficiency (EQE), chromaticity, and lifespan of sealing-layer-including, blue light-emitting elements in the display device in accordance with Embodiment 1 and sealing-layer-including, blue light-emitting elements in accordance with comparative examples.

FIG. 4 is a diagram listing the external quantum efficiency (EQE), chromaticity, and lifespan of sealing-layer-including, green light-emitting elements in the display device in accordance with Embodiment 1 and sealing-layer-including, green light-emitting elements in accordance with comparative examples.

FIG. 5 is a diagram listing the external quantum efficiency (EQE), chromaticity, and lifespan of sealing-layer-including, red light-emitting elements in the display device in accordance with Embodiment 1 and sealing-layer-including, red light-emitting elements in accordance with comparative examples.

FIG. 6 is a partially enlarged view of a pixel section in a display device in accordance with Embodiment 2.

FIG. 7 is a diagram listing the external quantum efficiency (EQE), chromaticity, and lifespan of sealing-layer-including, blue light-emitting elements in the display device in accordance with Embodiment 2, sealing-layer-including, blue light-emitting elements in the display device in accordance with Embodiment 1, and sealing-layer-including, blue light-emitting elements in accordance with comparative examples.

FIG. 8 is a partially enlarged view of a pixel section in a display device in accordance with Embodiment 3.

FIG. 9 is a diagram listing the external quantum efficiency (EQE), chromaticity, and lifespan of sealing-layer-including, blue light-emitting elements in the display device in accordance with Embodiment 3 and sealing-layer-including, blue light-emitting elements in accordance with comparative examples.

### DESCRIPTION OF EMBODIMENTS

The following will describe embodiments of the present invention with reference to FIGS. 1 to 9. Throughout the following, members of an embodiment that have the same arrangement and function as members of a specific embodiment are indicated by the same reference numerals and description thereof may be omitted for convenience of description.

### Embodiment 1

Portion (a) of FIG. 1 is a plan view of a display device 1 in accordance with Embodiment 1, and (b) of FIG. 1 is a cross-sectional view of a structure of the display device 1 in accordance with Embodiment 1.

As shown in (a) of FIG. 1, the display device 1 has: a display area DA including a plurality of pixels; and a frame area NDA surrounding the display area DA.

As shown in (b) of FIG. 1, the display device 1 includes a barrier layer 5, a TFT (thin film transistor) layer 6, red light-emitting elements 11R, green light-emitting elements 11G, blue light-emitting elements 11B, edge covers 8 (one each between light-emitting elements of different colors), a sealing layer 12, and a resin layer 13 all on or above the top face (light-emitting element side) of a substrate 4. Meanwhile, on the bottom face of the substrate 4 is there provided a lower substrate 17 via an adhesion layer 16.

The present embodiment describes an example where each pixel P in the display device 1 includes a red subpixel RSUB, a green subpixel GSUB, and a blue subpixel BSUB, the red subpixel RSUB includes one of the red light-emitting elements 11R, the green subpixel GSUB includes one of the green light-emitting elements 11G, and the blue subpixel BSUB includes one of the blue light-emitting elements 11B. This is however not the only possible implementation of the invention. Alternatively, each pixel P in the display device 1 may include a subpixel of another color.

There is provided a light-emitting element layer 11 on the TFT layer 6 in the display area DA. The light-emitting element layer 11 includes: first electrodes 7; functional layers 9R, 9G, 9B each including a light-emitting layer; and a second electrode 10, and is a layer in which the red light-emitting elements 11R, the green light-emitting elements 11G, and the blue light-emitting elements 11B, which emit different colors of light, are formed.

The substrate 4 and the lower substrate 17 are flexible substrates composed primarily of, for example, a resin such as a polyimide.

The barrier layer 5 is an inorganic insulation layer for preventing the intrusion of foreign materials such as water and oxygen and may be made of, for example, silicon nitride or silicon oxide.

The TFT layer 6 includes, among others: a plurality of thin film transistors; a plurality of capacitive elements; wiring lines for these transistors and elements; and various insulation films.

The red light-emitting elements 11R, the green light-emitting elements 11G, and the blue light-emitting elements 11B on the TFT layer 6 each include: one of the first electrodes 7 provided in an insular manner; the common, second electrode 10; and the functional layers 9R, 9G, 9B between the first electrode 7 and the second electrode 10. Note that the edge cover 8 is an insulation film for covering the edge of the first electrode 7.

The functional layer 9R in each red light-emitting element 11R includes a red light-emitting layer, the functional layer 9G in each green light-emitting element 11G includes a green light-emitting layer, and the functional layer 9B in each blue light-emitting element 11B includes a blue light-emitting layer.

The first electrodes 7 are anodes, and the second electrode 10 is a cathode, in the present embodiment. Therefore, the functional layer 9R, provided between the first electrode 7 and the second electrode 10 in each red light-emitting element 11R, includes a hole injection layer, a hole transport layer, a red light-emitting layer, an electron transport layer, and an electron injection layer, all of which are stacked in this order when viewed from the first electrode 7 side. In addition, the functional layer 9G, provided between the first electrode 7 and the second electrode 10 in each green light-emitting element 11G, includes a hole injection layer, a hole transport layer, a green light-emitting layer, an electron transport layer, and an electron injection layer, all of which are stacked in this order when viewed from the first electrode 7 side. Additionally, the functional layer 9B, provided between the first electrode 7 and the second electrode 10 in each blue light-emitting element 11B, includes a hole injection layer, a hole transport layer, a blue light-emitting layer, an electron transport layer, and an electron injection layer, all of which are stacked in this order when viewed from the first electrode 7 side. The functional layers 9R, 9G, 9B structured as described here are used in the present embodiment. This is however not the only possible implementation of the invention.

In the present embodiment, since the first electrodes 7 are anodes, the first electrodes 7 may be made of, for example, a stack of ITO (indium tin oxide) and Ag (silver), so as to be reflective to visible light.

In the present embodiment, since the second electrode 10 is a cathode, the second electrode 10 may be made of, for example, a thin metal film of, for example, a magnesium-silver alloy, so as to be transmissive to visible light. The present embodiment describes an example where the second electrode 10 is a common electrode. This is however not the only possible implementation of the invention. Alternatively, the second electrode 10 may be provided in an insular manner, and the first electrode be provided as a common electrode.

The edge cover 8 is formed by, for example, applying an organic material such as a polyimide or an acrylic resin and subsequently patterning the applied organic material by photolithography.

The present embodiment describes an example where the red light-emitting elements 11R, the green light-emitting elements 11G, and the blue light-emitting elements 11B are all OLEDs (organic light-emitting diodes). This is however not the only possible implementation of the invention. Alternatively, the red light-emitting elements 11R, the green light-emitting elements 11G, and the blue light-emitting elements 11B may be all QLEDs (quantum-dot light-emitting diodes) each including a quantum-dot layer as a light-emitting layer. Additionally, some of the red light-emitting elements 11R, the green light-emitting elements 11G, and the blue light-emitting elements 11B may be OLEDs, and the rest of the red light-emitting elements 11R, the green light-emitting elements 11G, and the blue light-emitting elements 11B may be QLEDs.

The sealing layer 12 for covering the red light-emitting elements 11R, the green light-emitting elements 11G, and the blue light-emitting elements 11B, that is, the sealing layer 12 provided on the light-emitting element layer 11 to seal the light-emitting element layer 11, prevents foreign materials such as water and oxygen from reaching inside the light-emitting elements of the associated color. Details will be given later.

The resin layer 13 may be made of an organic material such as a polyimide or an acrylic resin so as to cover the barrier layer 5 and the sealing layer 12.

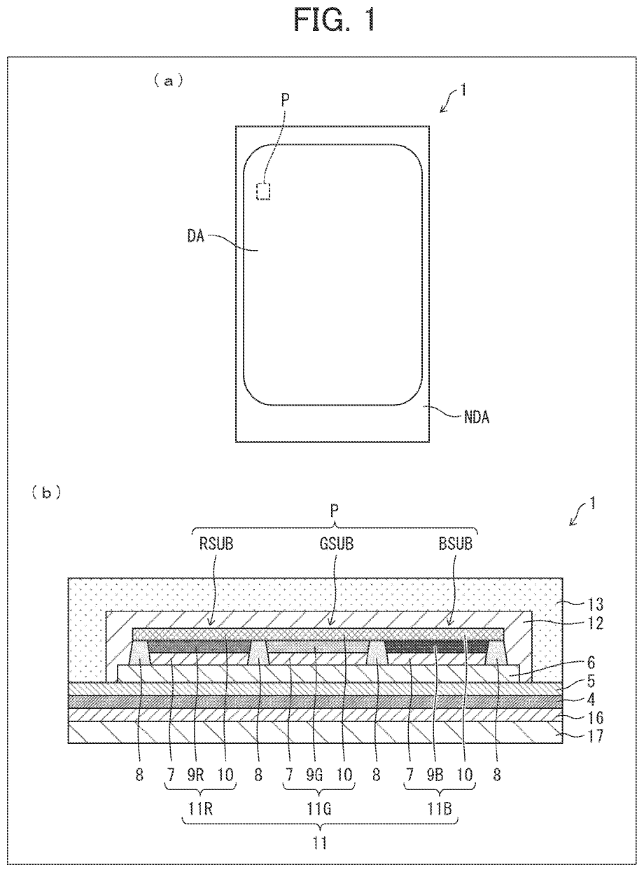

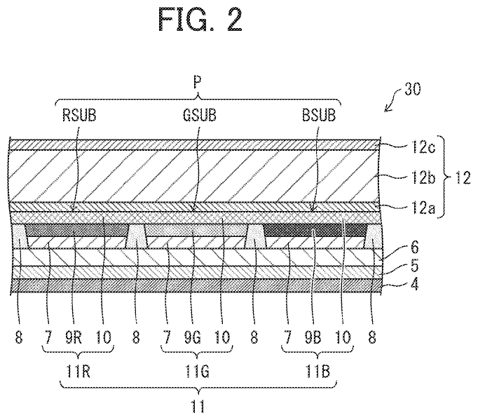

FIG. 2 is a partially enlarged view of a pixel section 30 in the display device 1 in accordance with Embodiment 1.

The present embodiment describes an example where the sealing layer 12 covering the red light-emitting elements 11R, the green light-emitting elements 11G, and the blue light-emitting elements 11B is a film including a first inorganic sealing film 12a, an organic sealing film 12b, and a second inorganic sealing film 12c, all of which are stacked in this order when viewed from the side of the red light-emitting elements 11R, the green light-emitting elements 11G, and the blue light-emitting elements 11B, as shown in FIG. 2. This is however not the only possible implementation of the invention, so long as the sealing layer 12 includes a stacked film in which the first inorganic sealing film 12a and the organic sealing film 12b are stacked in this order when viewed from the side of the red light-emitting elements 11R, the green light-emitting elements 11G, and the blue light-emitting elements 11B.

The present embodiment describes an example where the first inorganic sealing film 12a and the second inorganic sealing film 12c shown in FIG. 2 are silicon nitride (SiNx) films formed to a thickness of 0.5 μm by sputtering. This is however not the only possible implementation of the invention. Alternatively, the thickness of the silicon nitride film, although not limited in any particular manner, is preferably from 0.4 μm to 0.6 μm, both inclusive. In addition, the first inorganic sealing film 12a and the second inorganic sealing film 12c may be, for example, silicon oxide (SiOx) films and, for improved adhesion with the organic sealing film 12b, are preferably nitride films and may be, for example, silicon nitride (SiNx) films, silicon oxynitride (SiOxNy where x>y) films, or silicon nitroxide (SiNxOy where x>y) films. Additionally, the present embodiment describes an example where the first inorganic sealing film 12a and the second inorganic sealing film 12c are made of the same material with the same thickness. This is however not the only possible implementation of the invention. Alternatively, the first inorganic sealing film 12a and the second inorganic sealing film 12c may be made of different materials with different thicknesses.

The organic sealing film 12b shown in FIG. 2 includes a polymer compound and a cyclic compound. Since the polymer compound and the cyclic compound form an inclusion complex, the organic sealing film 12b contains an inclusion complex of the polymer compound and the cyclic compound.

In the present embodiment, the polymer compound is a methacrylic-based polymer (m=1 in chemical formula 3 below), and the cyclic compound is a cyclodextrin (chemical formula 2 below). The methacrylic-based polymer and the cyclodextrin therefore form an inclusion complex (chemical formula 1 below) of the methacrylic-based polymer and the cyclodextrin. Note that n is an integer greater than or equal to 1 in chemical formulas 1, 2, and 3 below and also that m is an integer greater than or equal to 1 in chemical formula 3 below.

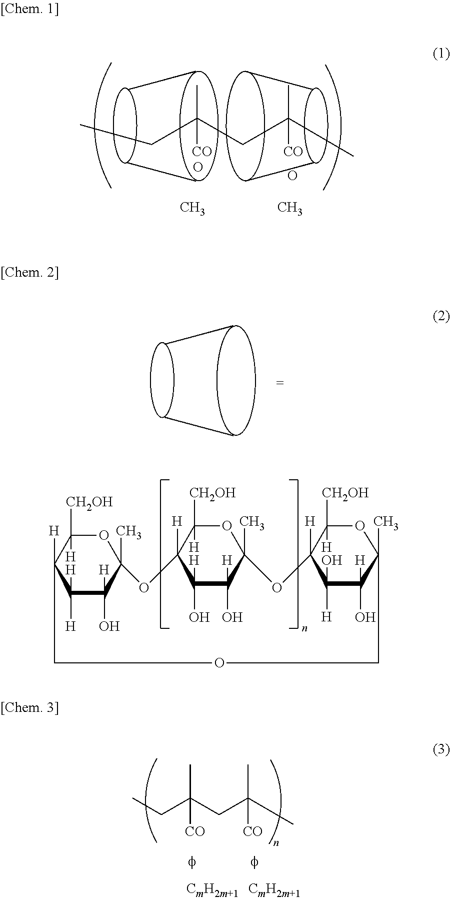

In the present embodiment, a 1:1 (weight ratio) mixed solution of the cyclodextrin (chemical formula 2) and the methacrylic-based polymer (m=1 in chemical formula 3 above) in a mixed solvent of ethanol and THF is applied onto the first inorganic sealing film 12a, and the entire mixture is heated at 80° C. for 20 minutes to remove the solvent, to prepare the organic sealing film 12b with a 2-μm thickness.

The cyclodextrin (chemical formula 2) is more polar than the methacrylic-based polymer (chemical formula 3) and has good affinity with the first inorganic sealing film 12a or the second inorganic sealing film 12c (particularly with a silicon nitride film). In addition, the cyclodextrin (chemical formula 2) is not particularly very soluble in water and is for this reason capable of efficiently restraining permeability to moisture and organic impurities when used in combination with the methacrylic-based polymer (chemical formula 3).

The organic sealing film 12b has good affinity with the first inorganic sealing film 12a, thereby leaving no space between the first inorganic sealing film 12a and the organic sealing film 12b. The organic sealing film 12b therefore does not need to have an increased thickness. The thickness of the organic sealing film 12b is preferably from 0.2 μm to 2.3 μm, both inclusive, and more preferably from 0.2 μm to 2.0 μm, both inclusive.

The organic sealing film 12b is preferably formed to a thickness of at least 0.2 μm because otherwise there may exist no organic molecules, in other words, there may develop a region where there is no organic sealing film, which could reduce the water-barrier property, if the organic sealing film 12b is formed by applying a liquid.

The organic sealing film 12b is preferably formed to a thickness of at most 2.3 μm because light may leak in an oblique direction and/or color may change if the organic sealing film is excessively thick.

Note that in view of ease in forming the inclusion complex (chemical formula 1 above) of a methacrylic-based polymer and a cyclodextrin, it is preferable to select a cyclodextrin that has such an n that the cyclodextrin (chemical formula 2 above) has an inner diameter of at least 0.45 nm. Note that the present embodiment uses a cyclodextrin with an inner diameter of 0.45 nm.

The sealing layer 12 in the display device 1 in accordance with the present embodiment includes a stacked film in which the first inorganic sealing film 12a and the organic sealing film 12b are stacked in this order when viewed from the side of the red light-emitting elements 11R, the green light-emitting elements 11G, and the blue light-emitting elements 11B. Specifically, since the sealing layer 12 is a film in which the first inorganic sealing film 12a, the organic sealing film 12b, and the second inorganic sealing film 12c are stacked in this order when viewed from the side of the red light-emitting elements 11R, the green light-emitting elements 11G, and the blue light-emitting elements 11B, the resultant display device 1 achieves zero retardation and both good barrier properties and good display performance. In other words, in the present embodiment, adherence can be improved both between the organic sealing film 12b and the first inorganic sealing film 12a and between the organic sealing film 12b and the second inorganic sealing film 12c, and a gap may be prevented from developing between these films. Therefore, erosion by, for example, water content and foreign materials can be prevented without having to increase the thickness of the organic sealing film 12b. Consequently, the occurrence of retardation due to an increase in the thickness of the organic sealing film 12b can be prevented, and the resultant display device 1 exhibits excellent viewing angle characteristics, in other words, excellent display performance.

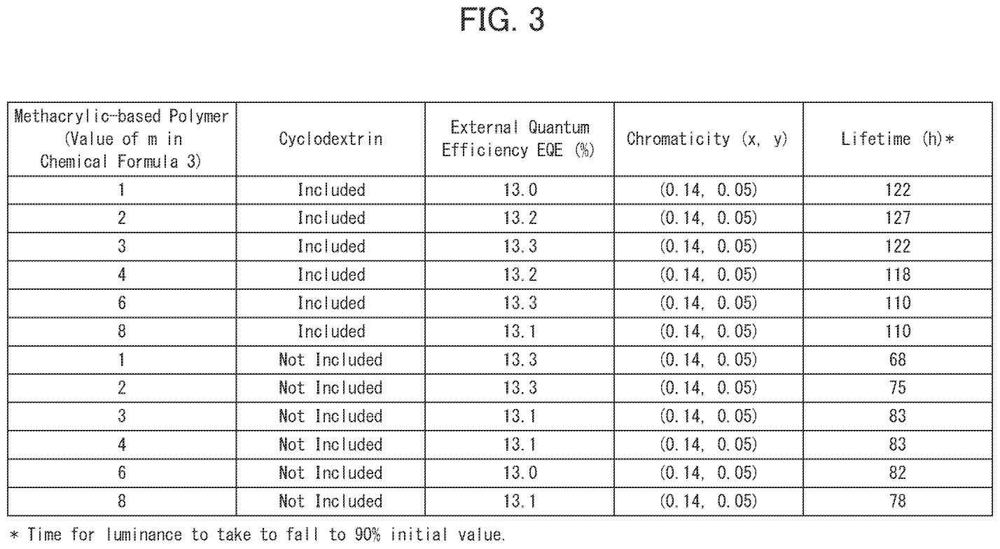

FIG. 3 is a diagram listing the external quantum efficiency (EQE), chromaticity, and lifespan of the sealing-layer-12-including, blue light-emitting elements 11B in the display device 1 in accordance with Embodiment 1 and sealing-layer-including, blue light-emitting elements 11B in accordance with comparative examples.

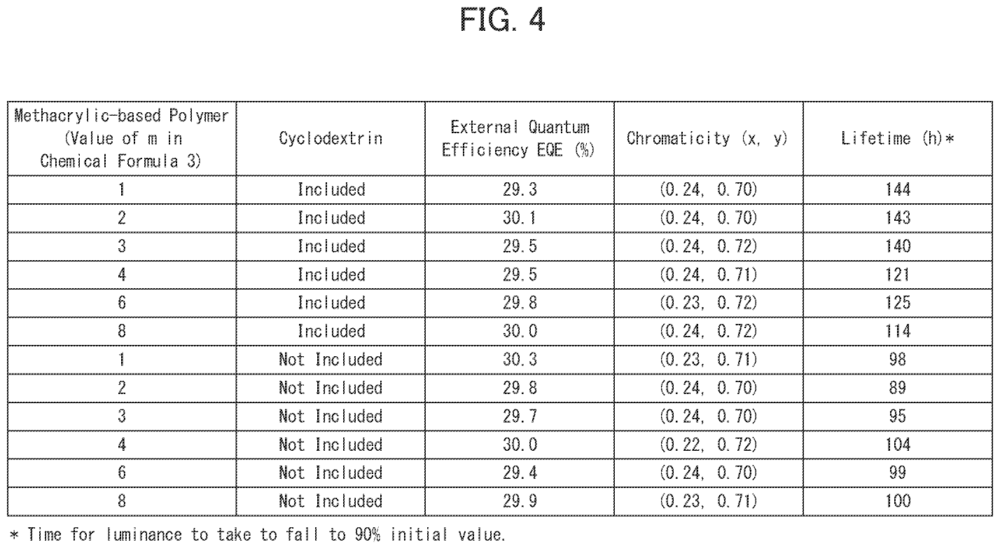

FIG. 4 is a diagram listing the external quantum efficiency (EQE), chromaticity, and lifespan of the sealing-layer-12-including, green light-emitting elements 11G in the display device 1 in accordance with Embodiment 1 and sealing-layer-including, green light-emitting elements 11G in accordance with comparative examples.

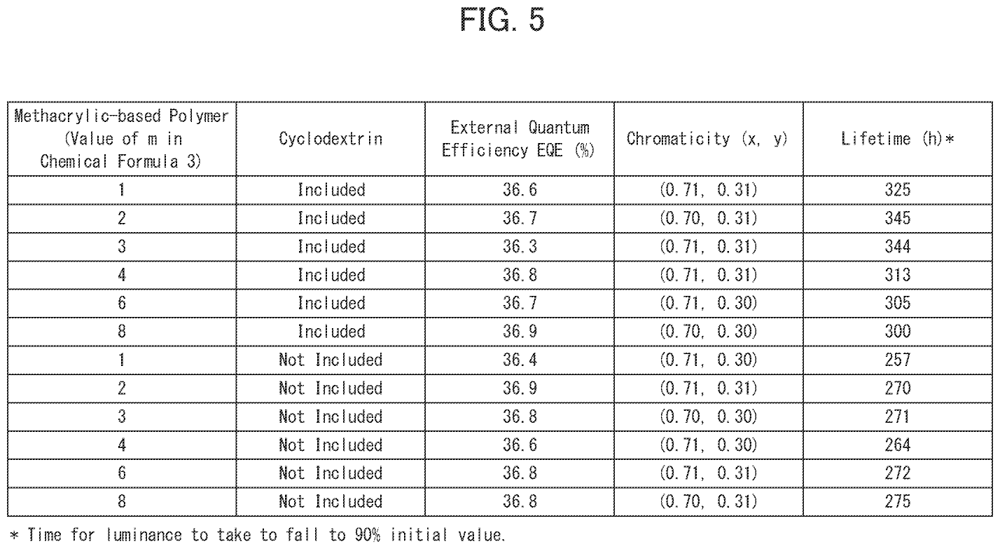

FIG. 5 is a diagram listing the external quantum efficiency (EQE), chromaticity, and lifespan of the sealing-layer-12-including, red light-emitting elements 11R in the display device 1 in accordance with Embodiment 1 and sealing-layer-including, red light-emitting elements 11R in accordance with comparative examples.

FIGS. 3 to 5 show results obtained from evaluations under the conditions detailed below.

Each sealing layer including a cyclodextrin listed in FIGS. 3 to 5 is a film in which the first inorganic sealing film 12a, the organic sealing film 12b, and the second inorganic sealing film 12c are stacked in this order when viewed from the side of the red light-emitting elements 11R, the green light-emitting elements 11G, and the blue light-emitting elements 11B. The first inorganic sealing film 12a and the second inorganic sealing film 12c are silicon nitride films formed by sputtering to a thickness of 0.5 μm. The organic sealing film 12b is a film formed with a thickness of 2 μm by applying, onto the first inorganic sealing film 12a, a 1:1 (weight ratio) mixed solution of a cyclodextrin (chemical formula 2) and a methacrylic-based polymer (chemical formula 3 above where m=1, 2, 3, 4, 6, or 8) in a solvent mixture of ethanol and THF and removing the solvent through heating for 20 minutes at 80° C.

Meanwhile, each sealing layer including no cyclodextrin listed in FIGS. 3 to 5 in accordance with a comparative example is a film in which the first inorganic sealing film 12a, an organic sealing film made only of a methacrylic-based polymer, and the second inorganic sealing film 12c are stacked in this order when viewed from the side of the red light-emitting elements 11R, the green light-emitting elements 11G, and the blue light-emitting elements 11B. The organic sealing film made only of a methacrylic-based polymer is a film formed with a thickness of 2 μm by applying, onto the first inorganic sealing film 12a, a solution of a methacrylic-based polymer (chemical formula 3 above where m=1, 2, 3, 4, 6, or 8) in a solvent mixture of ethanol and THF and removing the solvent through heating for 20 minutes at 80° C.

Note that all evaluations were performed without providing the resin layer 13, the adhesion layer 16, and the lower substrate 17 shown in FIG. 1.

In addition, the evaluations of driving lifespan of the blue light-emitting elements 11B and the red light-emitting elements 11R are results of a 50 mA/cm #<2># current driving test performed in an environment where the temperature was 45° C. and the humidity was 90%. The evaluations of driving lifespan of the green light-emitting elements 11G are results of a 30 mA/cm #<2># current driving test in the same environment.

Referring to FIG. 3, no differences were observed in the external quantum efficiency (EQE) and chromaticity of the sealing-layer-including, blue light-emitting elements 11B in any of the cases. In contrast, the sealing-layer-12-including, blue light-emitting elements 11B including the organic sealing film 12b containing a cyclodextrin, a methacrylic-based polymer, and an inclusion complex of the cyclodextrin and the methacrylic-based polymer had a longer driving lifespan than the sealing-layer-including, blue light-emitting elements 11B in accordance with comparative examples. Additionally, the sealing-layer-12-including, blue light-emitting elements 11B achieved a particularly long driving lifespan when the methacrylic-based polymer contained up to three alkyl groups, that is, when the methacrylic-based polymer was such that m=1, 2, or 3 in chemical formula 3 above. This is presumably because when the methacrylic-based polymer contains fewer alkyl groups, an inclusion complex is more likely to be formed, and a more uniform organic sealing film is formed. When no inclusion complex was formed (when no cyclodextrin was contained), the lifespan was much shorter.

Referring to FIG. 4, no differences were observed in the external quantum efficiency (EQE) and chromaticity of the sealing-layer-including, green light-emitting elements 11G in any of the cases. In contrast, the sealing-layer-12-including, green light-emitting elements 11G including the organic sealing film 12b containing a cyclodextrin, a methacrylic-based polymer, and an inclusion complex of the cyclodextrin and the methacrylic-based polymer had a longer driving lifespan than the sealing-layer-including, green light-emitting elements 11G in accordance with comparative examples. Additionally, the sealing-layer-12-including, green light-emitting elements 11G achieved a particularly long driving lifespan when the methacrylic-based polymer contained up to three alkyl groups, that is, when the methacrylic-based polymer was such that m=1, 2, or 3 in chemical formula 3 above. This is presumably because when the methacrylic-based polymer contains fewer alkyl groups, an inclusion complex is more likely to be formed, and a more uniform organic sealing film is formed. When no inclusion complex was formed (when no cyclodextrin was contained), the lifespan was much shorter.

Referring to FIG. 5, no differences were observed in the external quantum efficiency (EQE) and chromaticity of the sealing-layer-including, red light-emitting elements 11R in any of the cases. In contrast, the sealing-layer-12-including, red light-emitting elements 11R including the organic sealing film 12b containing a cyclodextrin, a methacrylic-based polymer, and an inclusion complex of the cyclodextrin and the methacrylic-based polymer had a longer driving lifespan than the sealing-layer-including, red light-emitting elements 11R in accordance with comparative examples. Additionally, the sealing-layer-12-including, red light-emitting elements 11R achieved a particularly long driving lifespan when the methacrylic-based polymer contained up to three alkyl groups, that is, when the methacrylic-based polymer was such that m=1, 2, or 3 in chemical formula 3 above. This is presumably because when the methacrylic-based polymer contains fewer alkyl groups, an inclusion complex is more likely to be formed, and a more uniform organic sealing film is formed. When no inclusion complex was formed (when no cyclodextrin was contained), the lifespan was much shorter.

For the methacrylic-based polymer of chemical formula 3 above contained in the organic sealing film 12b, m in chemical formula 3 above is preferably an integer from 1 to 12, more preferably an integer from 1 to 8, and most preferably an integer from 1 to 3.

The present embodiment has so far discussed an example where the organic sealing film 12b contains a cyclodextrin as a cyclic compound. This is however not the only possible implementation of the invention. Alternatively, for example, a crown ether or a cycloawaodorin may be used so long as the substance is more polar than the polymer compound contained in the organic sealing film 12b and has good affinity to the first inorganic sealing film 12a or the second inorganic sealing film 12c. Note that the crown ether or the cycloawaodorin preferably has such an inner diameter as to readily form an inclusion complex with a polymer compound. Additionally, at least one species selected from a cyclodextrin, a crown ether, and a cycloawaodorin may be used as the cyclic compound contained in the organic sealing film 12b.

In addition, the present embodiment has so far discussed an example where the organic sealing film 12b contains a methacrylic-based polymer of chemical formula 3 above as a polymer compound. This is however not the only possible implementation of the invention. Alternatively, at least one species selected from a methacrylic-based polymer, an acrylic-based polymer, a polyimide, a parylene, a polyester, a polyamide, and a polyaramide may be used as the polymer compound contained in the organic sealing film 12b.

In addition, the present embodiment describes an example where the first inorganic sealing film 12a and the second inorganic sealing film 12c are silicon nitride (SiNx) films. This is however not the only possible implementation of the invention. Alternatively, a film containing at least one of silicon oxide (SiOx), silicon nitride (SiNx), silicon oxynitride (SiOxNy where x>y), and silicon nitroxide (SiNxOy where x>y) may be used as the first inorganic sealing film 12a or the second inorganic sealing film 12c.

In addition, the present embodiment has so far discussed an example of results in cases where a silicon nitride (SiNx) film is used as the first inorganic sealing film 12a and the second inorganic sealing film 12c. The same results as the above-described results are obtained even if a film is used in which a single-layered inorganic insulation film of, for example, silicon oxide (SiOx), silicon oxynitride (SiOxNy where x>y), or silicon nitroxide (SiNxOy where x>y) is formed and even if a film is used in which inorganic insulation films of, for example, silicon oxide (SiOx), silicon nitride (SiNx), silicon oxynitride (SiOxNy where x>y), or silicon nitroxide (SiNxOy where x>y) are stacked.

### Embodiment 2

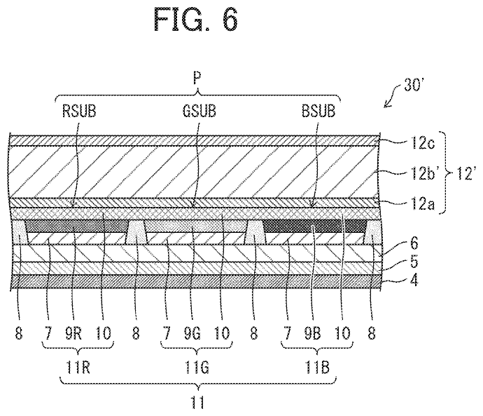

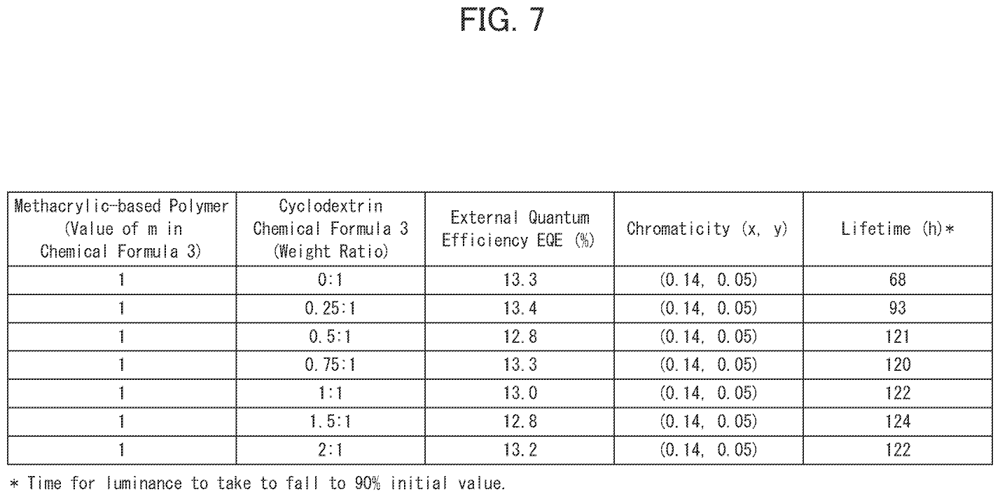

A description is now given of Embodiment 2 of the present invention with reference to FIGS. 6 and 7. A sealing layer 12′ in a display device in accordance with the present embodiment differs from Embodiment 1 in the weight ratio of the cyclic compound and the polymer compound in an organic sealing film 12b′. The sealing layer 12′ is otherwise as described in Embodiment 1. For convenience of description, members of the present embodiment that have the same function as members shown in the drawings for Embodiment 1 above are indicated by the same reference numerals, and description thereof is omitted.

FIG. 6 is a partially enlarged view of a pixel section 30′ in a display device in accordance with Embodiment 2.

The sealing layer 12′ in the display device in accordance with the present embodiment shown in FIG. 6 differs from Embodiment 1 in the weight ratio of the cyclic compound and the polymer compound in the organic sealing film 12b′. The above-described Embodiment 1 discussed cases where the cyclic compound and the polymer compound in the organic sealing film 12b had a weight ratio of 1:1. The present embodiment describes cases where the cyclic compound and the polymer compound in the organic sealing film 12b′ has a weight ratio of 0.25:1, 0.5:1, 0.75:1, 1.5:1, and 2:1.

FIG. 7 is a diagram listing the external quantum efficiency (EQE), chromaticity, and lifespan of the sealing-layer-12′-including, blue light-emitting elements 11B in the display device in accordance with Embodiment 2, the sealing-layer-12-including, blue light-emitting elements 11B in the display device in accordance with Embodiment 1 (the cyclodextrin and the methacrylic-based polymer have a weight ratio of 1:1 in FIG. 7), and the sealing-layer-including, blue light-emitting elements 11B in accordance with comparative examples (the cyclodextrin and the methacrylic-based polymer have a weight ratio of 0:1 in FIG. 7).

FIG. 7 shows results obtained from evaluations under the conditions detailed below.

Each sealing layer 12′ including a cyclodextrin listed in FIG. 7 is a film in which the first inorganic sealing film 12a, the organic sealing film 12b′, and the second inorganic sealing film 12c are stacked in this order when viewed from the side of the red light-emitting elements 11R, the green light-emitting elements 11G, and the blue light-emitting elements 11B. The first inorganic sealing film 12a and the second inorganic sealing film 12c are silicon nitride films formed by sputtering to a thickness of 0.5 sm. The organic sealing film 12b′ is a film formed with a thickness of 2 μm by applying, onto the first inorganic sealing film 12a, a 0.25:1, 0.5:1, 0.75:1, 1.5:1, or 2:1 (weight ratio) mixed solution of a cyclodextrin (chemical formula 2) and a methacrylic-based polymer (chemical formula 3 above where m=1) in a solvent mixture of ethanol and THF and removing the solvent through heating for 20 minutes at 80° C.

Meanwhile, each sealing layer including no cyclodextrin listed in FIG. 7 in accordance with a comparative example is a film in which the first inorganic sealing film 12a, an organic sealing film made only of a methacrylic-based polymer, and the second inorganic sealing film 12c are stacked in this order when viewed from the side of the red light-emitting elements 11R, the green light-emitting elements 11G, and the blue light-emitting elements 11B. The organic sealing film made only of a methacrylic-based polymer is a film formed with a thickness of 2 μm by applying, onto the first inorganic sealing film 12a, a solution of a methacrylic-based polymer (chemical formula 3 above where m=1) in a solvent mixture of ethanol and THF and removing the solvent through heating for 20 minutes at 80° C.

Note that all evaluations were performed without providing the resin layer 13, the adhesion layer 16, and the lower substrate 17 shown in FIG. 1.

In addition, the evaluations of driving lifespan are results of a 50 mA/cm #<2># current driving test performed in an environment where the temperature was 45° C. and the humidity was 90%.

Referring to FIG. 7, no differences were observed in the external quantum efficiency (EQE) and chromaticity of the sealing-layer-including, blue light-emitting elements 11B in any of the cases. In contrast, the driving lifespan was longer when the cyclodextrin accounted for a weight ratio of at least 0.25, and hence an inclusion complex was more likely to be formed, than the sealing-layer-including, blue light-emitting elements 11B in accordance with comparative examples. Note that the lifespan substantially saturated when the cyclodextrin accounted for a weight ratio of at least 0.25.

From the description so far, the weight ratio of the cyclic compound to the polymer compound in the organic sealing film 12b′ in the sealing layer 12′ in the display device in accordance with the present embodiment is preferably 0.25:1 or greater.

Since the display device in accordance with the present embodiment includes the sealing layer 12′, the display device can prevent the occurrence of retardation and achieve both good barrier properties and good display performance similarly to Embodiment 1.

### Embodiment 3

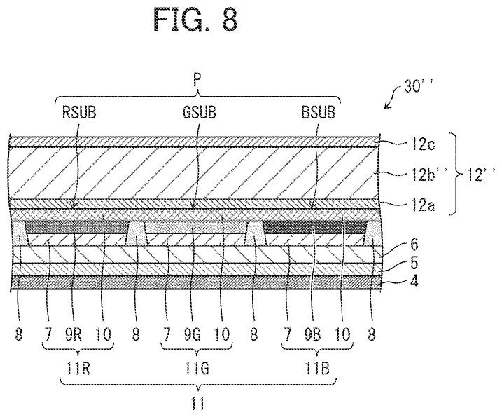

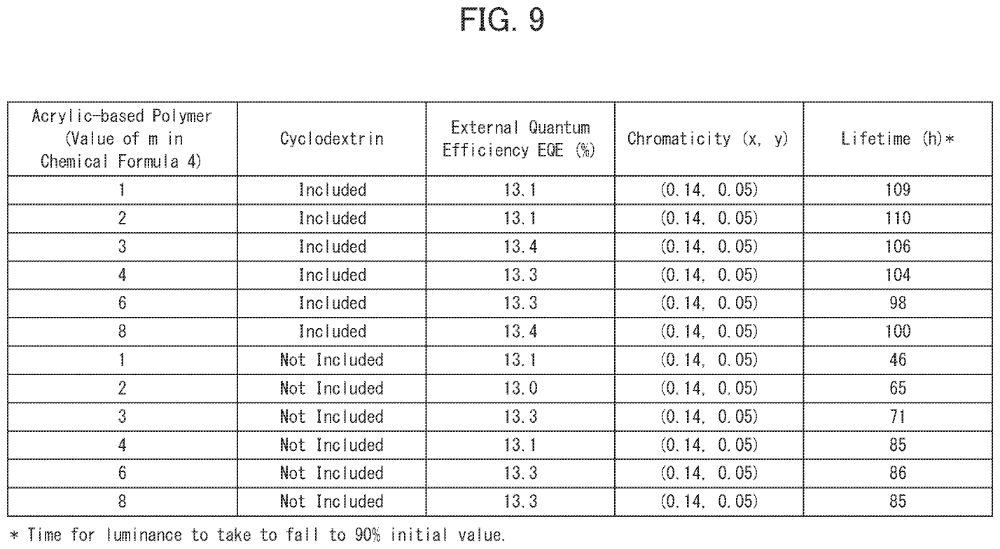

A description is now given of Embodiment 3 of the present invention with reference to FIGS. 8 and 9. A sealing layer 12″ in a display device in accordance with the present embodiment differs from Embodiments 1 and 2 in that an acrylic-based polymer is used as the polymer compound contained in an organic sealing film 12b″ and is otherwise as described in Embodiments 1 and 2. For convenience of description, members of the present embodiment that have the same function as members shown in the drawings for Embodiments 1 and 2 above are indicated by the same reference numerals, and description thereof is omitted.

FIG. 8 is a partially enlarged view of a pixel section 30″ in the display device in accordance with Embodiment 3.

In the sealing layer 12″ in the display device in accordance with the present embodiment shown in FIG. 8, the polymer compound in the organic sealing film 12b″ is the acrylic-based polymer of chemical formula 4 below. Note that in chemical formula 4 below, m and n are integers greater than or equal to 1.

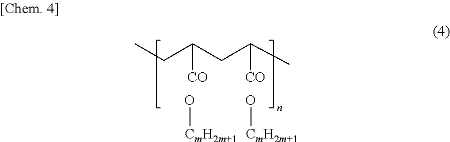

FIG. 9 is a diagram of the external quantum efficiency (EQE), chromaticity, and lifespan of sealing-layer-12″-including, blue light-emitting elements 11B in the display device in accordance with Embodiment 3 and sealing-layer-including, blue light-emitting element 11B in accordance with comparative examples.

FIG. 9 shows results obtained from evaluations under the conditions detailed below.

Each sealing layer 12″ including a cyclodextrin listed in FIG. 9 is a film in which the first inorganic sealing film 12a, the organic sealing film 12b″, and the second inorganic sealing film 12c are stacked in this order when viewed from the side of the red light-emitting elements 11R, the green light-emitting elements 11G, and the blue light-emitting elements 11B. The first inorganic sealing film 12a and the second inorganic sealing film 12c are silicon nitride films formed by sputtering to a thickness of 0.5 μm. The organic sealing film 12b″ is a film formed with a thickness of 2 μm by applying, onto the first inorganic sealing film 12a, a 1:1 (weight ratio) mixed solution of a cyclodextrin (chemical formula 2) and an acrylic-based polymer (chemical formula 4 above where m=1, 2, 3, 4, 6, or 8) in a solvent mixture of ethanol and THF and removing the solvent through heating for 20 minutes at 80° C. Meanwhile, each sealing layer including no cyclodextrin listed in FIG. 9 in accordance with a comparative example is a film in which the first inorganic sealing film 12a, an organic sealing film made only of an acrylic-based polymer, and the second inorganic sealing film 12c are stacked in this order when viewed from the side of the red light-emitting elements 11R, the green light-emitting elements 11G, and the blue light-emitting elements 11B. The organic sealing film made only of an acrylic-based polymer is a film formed with a thickness of 2 μm by applying, onto the first inorganic sealing film 12a, a solution of an acrylic-based polymer (chemical formula 4 above where m=1, 2, 3, 4, 6, or 8) in a solvent mixture of ethanol and THF and removing the solvent through heating for 20 minutes at 80° C.

Note that all evaluations were performed without providing the resin layer 13, the adhesion layer 16, and the lower substrate 17 shown in FIG. 1.

In addition, the evaluations of driving lifespan are results of a 50 mA/cm #<2># current driving test performed in an environment where the temperature was 45° C. and the humidity was 90%.

Referring to FIG. 9, no differences were observed in the external quantum efficiency (EQE) and chromaticity of the sealing-layer-including, blue light-emitting elements 11B in any of the cases. In contrast, the sealing-layer-12″-including, blue light-emitting elements 11B including the organic sealing film 12b″ containing a cyclodextrin, an acrylic-based polymer, and an inclusion complex of the cyclodextrin and the acrylic-based polymer had a longer driving lifespan than the sealing-layer-including, blue light-emitting elements 11B in accordance with comparative examples. Additionally, the sealing-layer-12″-including, blue light-emitting elements 11B achieved an even longer driving lifespan when the acrylic-based polymer contained up to three alkyl groups, that is, when the acrylic-based polymer is such that m=1, 2, or 3 in chemical formula 4 above. This is presumably because when the acrylic-based polymer contains fewer alkyl groups, an inclusion complex is more likely to be formed, and a more uniform organic sealing film is formed. When no inclusion complex was formed (when no cyclodextrin was contained), the lifespan was much shorter.

For the acrylic-based polymer of chemical formula 4 above contained in the organic sealing film 12b″, m in chemical formula 4 above is preferably an integer from 1 to 12, more preferably an integer from 1 to 8, and most preferably an integer from 1 to 3.

Since the display device in accordance with the present embodiment includes the sealing layer 12″, the display device can prevent the occurrence of retardation and achieve both good barrier properties and good display performance similarly to Embodiment 1.

Note that the lifespan was shorter when the acrylic-based polymer of chemical formula 4 above was used as the polymer compound in the organic sealing film of the sealing layer than when the methacrylic-based polymer of chemical formula 3 above was used as the polymer compound. This is presumably because the acrylic-based polymer has higher moisture permeability than the methacrylic-based polymer.

### GENERAL DESCRIPTION

### Aspect 1

A display device including:

a display area including a plurality of pixels;

a frame area surrounding the display area;

a thin film transistor layer;

a light-emitting element layer on the thin film transistor layer in the display area, the light-emitting element layer including a plurality of light-emitting elements that each include a first electrode, a light-emitting layer, and a second electrode and that emit light of different colors: and

a sealing layer disposed on the light-emitting element layer to seal the light-emitting element layer, wherein

the sealing layer includes a first inorganic sealing film on the light-emitting element layer and an organic sealing film on the first inorganic sealing film, and

the organic sealing film contains a polymer compound and a cyclic compound.

### Aspect 2

The display device of aspect 1, wherein the sealing layer further includes a second inorganic sealing film on the organic sealing film.

### Aspect 3

The display device of aspect 1 or 2, wherein the first inorganic sealing film contains at least one of silicon oxide (SiOx), silicon nitride (SiNx), silicon oxynitride (SiOxNy where x>y), and silicon nitroxide (SiNxOy where x>y).

### Aspect 4

The display device of aspect 2, wherein the second inorganic sealing film contains at least one of silicon oxide (SiOx), silicon nitride (SiNx), silicon oxynitride (SiOxNy where x>y), and silicon nitroxide (SiNxOy where x>y).

### Aspect 5

The display device of any one of aspects 1 to 4, wherein the organic sealing film contains an inclusion complex of the polymer compound and the cyclic compound.

### Aspect 6

The display device of any one of aspects 1 to 5, wherein the cyclic compound is at least one species selected from a cyclodextrin, a crown ether, and a cycloawaodorin.

### Aspect 7

The display device of any one of aspects 1 to 6, wherein the polymer compound is at least one species selected from a methacrylic-based polymer, an acrylic-based polymer, a polyimide, a parylene, a polyester, a polyamide, and a polyaramide.

### Aspect 8

The display device of any one of aspects 1 to 6, wherein the polymer compound is a methacrylic-based polymer of chemical formula 3 where m is an integer from 1 to 12 and n is an integer greater than or equal to 1.

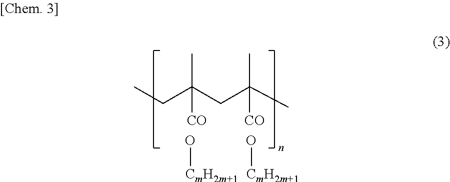

### Aspect 9

The display device of aspect 8, wherein in chemical formula 3, m is an integer from 1 to 8.

### Aspect 10

The display device of aspect 9, wherein in chemical formula 3, m is an integer from 1 to 3.

### Aspect 11

The display device of any one of aspects 1 to 6, wherein the polymer compound is an acrylic-based polymer of chemical formula 4 where m is an integer from 1 to 12 and n is an integer greater than or equal to 1.

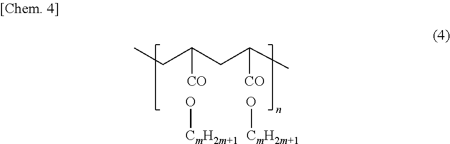

### Aspect 12

The display device of aspect 11, wherein in chemical formula 4, m is an integer from 1 to 8.

### Aspect 13

The display device of aspect 12, wherein in chemical formula 4, m is an integer from 1 to 3.

### Aspect 14

The display device of any one of aspects 1 to 13, wherein the first inorganic sealing film has a thickness of from 0.4 μm to 0.6 μm, both inclusive.

### Aspect 15

The display device of any one of aspects 3 to 14, wherein

the sealing layer further includes a second inorganic sealing film on the organic sealing film, and

the second inorganic sealing film has a thickness of from 0.4 μm to 0.6 μm, both inclusive.

### Aspect 16

The display device of any one of aspects 1 to 15, wherein the organic sealing film has a thickness of from 0.2 μm to 2.3 μm, both inclusive.

### Aspect 17

The display device of any one of aspects 1 to 15, wherein the cyclic compound and the polymer compound in the organic sealing film have a weight ratio of 0.25:1 or greater.

### Aspect 18

The display device of any one of aspects 1 to 17, wherein the plurality of light-emitting elements are organic light-emitting diodes or quantum-dot light-emitting diodes.

### Additional Remarks

The present invention is not limited to the description of the embodiments above and may be altered within the scope of the claims. Embodiments based on a proper combination of technical means disclosed in different embodiments are encompassed in the technical scope of the present invention. Furthermore, new technological features can be created by combining different technical means disclosed in the embodiments.

### INDUSTRIAL APPLICABILITY

The present invention is applicable to display devices.

### REFERENCE SIGNS LIST

1 Display Device
6 Thin Film Transistor Layer
7 First Electrode
9R, 9G, 9B Functional Layer Including Light-emitting Layer (Light-emitting Layer)
10 Second Electrode
11 Light-emitting Element Layer
11R, 11G, 11B Light-emitting Element
12, 12′, 12″ Sealing Layer
12a First Inorganic Sealing Film
12b, 12b′, 12b″ Organic Sealing Film
12c Second Inorganic Sealing Film
P Pixel
DA Display Area
NDA Frame Area

1. A display device comprising:
a display area including a plurality of pixels;
a frame area surrounding the display area;
a thin film transistor layer;
a light-emitting element layer on the thin film transistor layer in the display area, the light-emitting element layer including a plurality of light-emitting elements that each include a first electrode, a light-emitting layer, and a second electrode and that emit light of different colors; and
a sealing layer disposed on the light-emitting element layer to seal the light-emitting element layer, wherein
the sealing layer includes a first inorganic sealing film on the light-emitting element layer and an organic sealing film on the first inorganic sealing film,
the organic sealing film contains a polymer compound and a cyclic compound, and
the organic sealing film contains an inclusion complex of the polymer compound and the cyclic compound.

2. The display device according to claim 1, wherein the sealing layer further includes a second inorganic sealing film on the organic sealing film.

3. The display device according to claim 1, wherein the first inorganic sealing film contains at least one of silicon oxide (SiOx), silicon nitride (SiNx), silicon oxynitride (SiOxNy where x>y), and silicon nitroxide (SiNxOy where x>y).

4. The display device according to claim 2, wherein the second inorganic sealing film contains at least one of silicon oxide (SiOx), silicon nitride (SiNx), silicon oxynitride (SiOxNy where x>y), and silicon nitroxide (SiNxOy where x>y).

5. (canceled)

6. A display device comprising:
a display area including a plurality of pixels;
a frame area surrounding the display area;
a thin film transistor layer;
a light-emitting element layer on the thin film transistor layer in the display area, the light-emitting element layer including a plurality of light-emitting elements that each include a first electrode, a light-emitting layer, and a second electrode and that emit light of different colors; and
a sealing layer disposed on the light-emitting element layer to seal the light-emitting element layer, wherein
the sealing layer includes a first inorganic sealing film on the light-emitting element layer and an organic sealing film on the first inorganic sealing film,
the organic sealing film contains a polymer compound and a cyclic compound, and
the cyclic compound is at least one species selected from a cyclodextrin, a crown ether, and a cycloawaodorin.

7. The display device according to claim 1, wherein the polymer compound is at least one species selected from a methacrylic-based polymer, an acrylic-based polymer, a polyimide, a parylene, a polyester, a polyamide, and a polyaramide.

8. The display device according to claim 1, wherein the polymer compound is a methacrylic-based polymer of chemical formula 3 where m is an integer from 1 to 12 and n is an integer greater than or equal to 1.

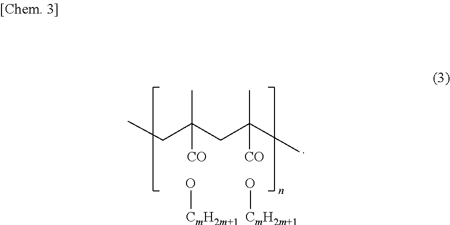

9. The display device according to claim 8, wherein in chemical formula 3, m is an integer from 1 to 8.

10. The display device according to claim 9, wherein in chemical formula 3, m is an integer from 1 to 3.

11. The display device according to claim 1, wherein the polymer compound is an acrylic-based polymer of chemical formula 4 where m is an integer from 1 to 12 and n is an integer greater than or equal to 1.

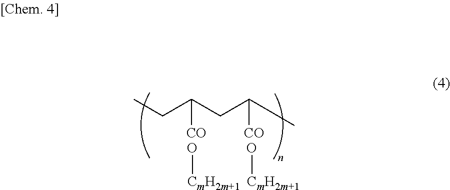

12. The display device according to claim 11, wherein in chemical formula 4, m is an integer from 1 to 8.

13. The display device according to claim 12, wherein in chemical formula 4, m is an integer from 1 to 3.

14. The display device according to claim 1, wherein the first inorganic sealing film has a thickness of from 0.4 μm to 0.6 μm, both inclusive.

15. The display device according to claim 3, wherein
the sealing layer further includes a second inorganic sealing film on the organic sealing film, and
the second inorganic sealing film has a thickness of from 0.4 μm to 0.6 μm, both inclusive.

16. The display device according to claim 1, wherein the organic sealing film has a thickness of from 0.2 μm to 2.3 μm, both inclusive.

17. The display device according to claim 1, wherein the cyclic compound and the polymer compound in the organic sealing film have a weight ratio of 0.25:1 or greater.

18. The display device according to claim 1, wherein the plurality of light-emitting elements are organic light-emitting diodes or quantum-dot light-emitting diodes.

19. The display device according to claim 6, wherein the sealing layer further includes a second inorganic sealing film on the organic sealing film.

20. The display device according to claim 6, wherein the first inorganic sealing film contains at least one of silicon oxide (SiOx), silicon nitride (SiNx), silicon oxynitride (SiOxNy where x>y), and silicon nitroxide (SiNxOy where x>y).

21. The display device according to claim 6, wherein the second inorganic sealing film contains at least one of silicon oxide (SiOx), silicon nitride (SiNx), silicon oxynitride (SiOxNy where x>y), and silicon nitroxide (SiNxOy where x>y).
